(19) United States
(12) Patent Application Publication
(10) Pub. No.: US 2023/0422348 A1
(43) Pub. Date: Dec. 28, 2023

(54) SUBSTRATE PROCESSING APPARATUS AND SUBSTRATE PROCESSING METHOD

(71) Applicant: Tokyo Electron Limited, Tokyo (JP)

(72) Inventors: Yasuaki KIKUCHI, Iwate (JP); Tatsuya YAMAGUCHI, Tokyo (JP); SungDuk SON, Gyeonggi-do (KR); Miki OUCHI, Iwate (JP); Nobuyuki HIROTA, Iwate (JP); Shingo HISHIYA, Yamanashi (JP)

(21) Appl. No.: 18/210,338

(22) Filed: Jun. 15, 2023

(30) Foreign Application Priority Data
Jun. 23, 2022 (JP) 2022-101428

(51) Int. Cl. H05B 1/02

(52) U.S. Cl. CPC H05B 1/023

(57) ABSTRACT

A substrate processing apparatus includes a processing container in which a plurality of substrates are processed; a plurality of heaters configured to control a temperature of the plurality of substrates accommodated in the processing container for each of a plurality of zones; and a controller configured to control an operation of the plurality of heaters. The controller is configured to control the plurality of heaters to a set temperature set in advance for each of the plurality of zones, thereby performing a processing on the plurality of substrates accommodated in the processing container, determine whether an abnormality determination condition is satisfied, including that an output value of at least one heater of the plurality of heaters is equal to or less than a heater control resolution, and issue a warning for the set temperature for each of the plurality of zones based on a result of the determining.

### CROSS-REFERENCE TO RELATED APPLICATIONS

This application is based on and claims priority from Japanese Patent Application No. 2022-101428 filed on Jun. 23, 2022 with the Japan Patent Office, the disclosure of which is incorporated herein in its entirety by reference.

### TECHNICAL FIELD

The present disclosure relates to a substrate processing apparatus and a substrate processing method.

### BACKGROUND

Japanese Patent Laid-Open Publication No. 2021-044282 discloses a substrate processing apparatus including a reaction tube, a heater cylinder provided with a heater for each of a plurality of zones, and a plurality of heater temperature sensors that measure the temperature of the heater corresponding to each zone, and a temperature adjuster that adjusts the temperature for each zone by controlling power supplied to each heater based on temperature measurement data.

### SUMMARY

According to an aspect of the present disclosure, a substrate processing apparatus includes a processing container in which a plurality of substrates are processed; a plurality of heaters configured to control a temperature of the plurality of substrates accommodated in the processing container for each of a plurality of zones; and a controller configured to control an operation of the plurality of heaters. The controller is configured to control the plurality of heaters to a set temperature set in advance for each of the plurality of zones, thereby performing a processing on the plurality of substrates accommodated in the processing container, determine whether an abnormality determination condition is satisfied, including that an output value of at least one heater of the plurality of heaters is equal to or less than a heater control resolution, and issue a warning for the set temperature for each of the plurality of zones based on a result of the determining.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a substrate processing apparatus according to an embodiment.

FIGS. 2A to 2C are diagrams illustrating an example of temperature control results by heaters in three substrate processing apparatuses.

FIGS. 3A to 3C are diagrams illustrating an example of temperature control results by a heater in a substrate processing apparatus.

FIGS. 4A and 4B are diagrams illustrating set temperatures and heater output results according to an embodiment.

FIG. 5 is a flowchart illustrating an example of a substrate processing method according to an embodiment.

FIGS. 6A and 6B are diagrams illustrating an example of automatic calculation of set temperatures according to one embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of the present disclosure will be described with reference to the drawings. In the respective drawings, the same components may be denoted by the same reference numerals, and overlapping descriptions thereof may be omitted.

[Substrate Processing Apparatus]

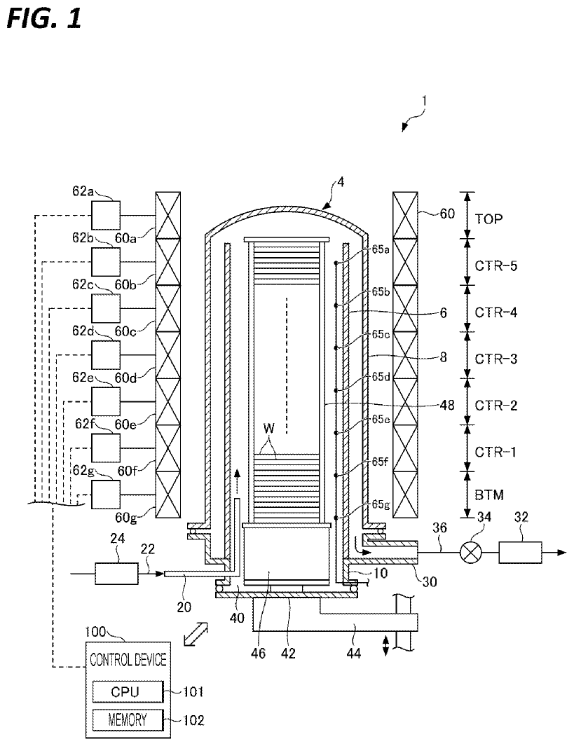

Referring to FIG. 1, descriptions will be made on a configuration of a substrate processing apparatus 1 according to an embodiment capable of executing a substrate processing method to be described later. FIG. 1 is a schematic cross-sectional view illustrating an example of the substrate processing apparatus 1 according to the embodiment. The substrate processing apparatus 1 of the present disclosure includes a substantially cylindrical processing container 4 whose longitudinal direction is vertical. The processing container 4 has a dual pipe structure including an inner cylinder 6 of a cylindrical body and an outer cylinder 8 having a ceiling, which is arranged coaxially outside the inner cylinder 6. The inner cylinder 6 and the outer cylinder 8 are made of a heat-resistant material such as, for example, quartz. However, the substrate processing apparatus 1 may have a single tube structure having one cylindrical body. A substrate processing (e.g., a film formation processing) is performed on a plurality of substrates inside the processing container 4.

The inner cylinder 6 and the outer cylinder 8 are held at the lower end portions thereof by a manifold 10 made of, for example, stainless steel. The manifold 10 is fixed to, for example, a base plate (not illustrated). Since the manifold 10 forms a substantially cylindrical internal space together with the inner cylinder 6 and the outer cylinder 8, it is assumed that the manifold 10 forms a part of the processing container 4.

That is, the processing container 4 includes the inner cylinder 6 and the outer cylinder 8 made of a heat-resistant material (e.g., quartz), and a manifold 10 made of, for example, stainless steel. The manifold 10 is provided in the lower portion of the lateral surface of the processing container 4 to hold the inner cylinder 6 and the outer cylinder 8 from the lower side.

The manifold 10 is provided with a gas introduction portion 20 to introduce a processing gas used for a substrate processing, into the processing container 4. Although FIG. 1 illustrates a configuration in which one gas introduction portion 20 is provided, the present disclosure is not limited thereto. A plurality of gas introduction portions 20 may be provided depending on, for example, the kind of gas to be used.

The gas introduction portion 20 is connected with an introduction pipe 22 to introduce the processing gas into the processing container 4. The introduction pipe 22 includes, for example, a flow rate adjuster 24 (e.g., a mass flow controller) for adjusting the gas flow rate and a valve (not illustrated).

Further, the manifold 10 is provided with a gas exhaust portion 30 to exhaust the atmosphere inside the processing container 4. The gas exhaust portion 30 is connected with an exhaust pipe 36 including a vacuum pump 32 and an opening variable valve 34, which are capable of controllably decompressing the inside of the processing container 4. A furnace opening 40 is formed in the lower end portion of the manifold 10, and the furnace opening 40 is provided with a disk-like lid 42 made of, for example, stainless steel. The lid 42 is provided to be elevatable by, for example, an elevating mechanism 44 that functions as a boat elevator, and is configured to hermetically seal the furnace opening 40.

A heat reserving tube 46 made of, for example, quartz is provided on the lid 42. A wafer boat 48 made of, for example, quartz is placed on the heat reserving tube 46 to hold, for example, a plurality of (e.g., about 50 to 200) wafers W in a horizontal state at predetermined intervals in multi-tiers. The substrate W may be, for example, a wafer having a diameter of 200 mm to 300 mm. The plurality of wafers W placed on the wafer boat 48 constitute one batch, and various substrate processings are performed by one batch.

The wafer boat 48 is loaded (carried in) to the inside of the processing container 4 by moving up the lid 42 using the elevating mechanism 44, and various film forming processes are performed on the wafers W held in the wafer boat 48. After various substrate processings are performed, the wafer boat 48 is unloaded (carried out) from the inside of the processing container 4 to the lower loading region by moving down the lid 42 using the elevating mechanism 44. The wafer boat 48 is an example of a boat configured to accommodate a plurality of substrates vertically within the processing container 4.

For example, a cylindrical heater 60, which is capable of controllably heating the processing container 4 to a predetermined temperature, is provided on the outer peripheral side of the processing container 4. The heater 60 has a plurality of heaters to 60g for controlling the temperature of the plurality of substrates W accommodated inside the processing container 4 for each of a plurality of zones.

The heater 60 is provided with heaters 60a to 60g from the upper side to the lower side in the vertical direction. The heaters 60a to 60g are configured such that their output values (power, calorific value) are able to be independently controlled by power controllers 62a to 62g, respectively. Further, temperature sensors 65a to 65g are installed inside the inner cylinder 6, corresponding to the heaters 60a to 60g. As the temperature sensors 65a to 65g, for example, thermocouples or temperature measuring resistors may be used. The temperature sensors 65a to 65g are also collectively referred to as a temperature sensor 65.

The heaters 60a to 60g are provided for each zone, corresponding to each zone when the substrate accommodating region of the wafer boat 48 is divided into a plurality of zones. In the substrate processing apparatus 1 of the present disclosure, as an example, the wafer boat 48 is divided into seven zones. The seven zones are called “BTM,” “CTR-1,” “CTR-2,” “CTR-3,” “CTR-4,” “CTR-5,” and “TOP” in order from the bottom.

The heater 60a heats a plurality of substrates in the “TOP” zone. The temperature sensor 65a measures the temperature of the “TOP” zone inside the inner cylinder 6. Hereinafter, the temperature of each zone within the inner cylinder 6 is also simply referred to as the temperature of the zone. The heater 60b heats a plurality of substrates in the “CTR-5” zone. The temperature sensor 65b measures the temperature of the “CTR-5” zone. The heater 60c heats a plurality of substrates in the “CTR-4” zone. The temperature sensor 65c measures the temperature of the “CTR-4” zone. The heater 60d heats a plurality of substrates in the “CTR-3” zone. The temperature sensor 65d measures the temperature of the “CTR-3” zone. The heater 60e heats a plurality of substrates in the “CTR-2” zone. The temperature sensor 65e measures the temperature of the “CTR-2” zone. The heater 60f heats a plurality of substrates in the “CTR-1” zone. The temperature sensor 65f measures the temperature of the “CTR-1” zone. The heater heats a plurality of substrates in the “BTM” zone. The temperature sensor 65g measures the temperature of the “BTM” zone.

The control device 100 controls the overall operation of the processing apparatus 1. The control device 100 includes a CPU 101 and a memory 102. The CPU 101 is a computer for controlling the overall operation of the substrate processing apparatus 1.

The memory 102 stores a control program for implementing various processings performed in the substrate processing apparatus 1 by the control of the control device 100, and recipe in which a substrate processing procedure is set for each step. Further, the memory 102 stores various programs for causing each part of the substrate processing apparatus 1 to perform the substrate processing according to the film formation condition (film formation step) set in the recipe. The various programs may be stored in a storage medium and then stored in the memory 102. The storage medium may be a hard disk or a semiconductor memory, or may be a portable medium such as a CD-ROM, a DVD, or a flash memory. Further, the programs, parameters, and various data may be appropriately transmitted from another device or host computer to the memory 102 by wired or wireless communication units. The control device 100 may be provided separately from the substrate processing apparatus 1. Further, the memory 102 may be a storage device provided separately from the substrate processing apparatus 1.

Detection signals from the temperature sensors 65 a to 65 g are transmitted to the control device 100. The control device 100 calculates set values for power controllers 62a to 62g based on the detection signals from the temperature sensors 65a to and outputs the calculated set values to power controllers 62a to 62g, respectively. Thus, the output value (Power) of each of the heaters 60a to 60g is controlled independently.

[Example of Temperature Control Results]

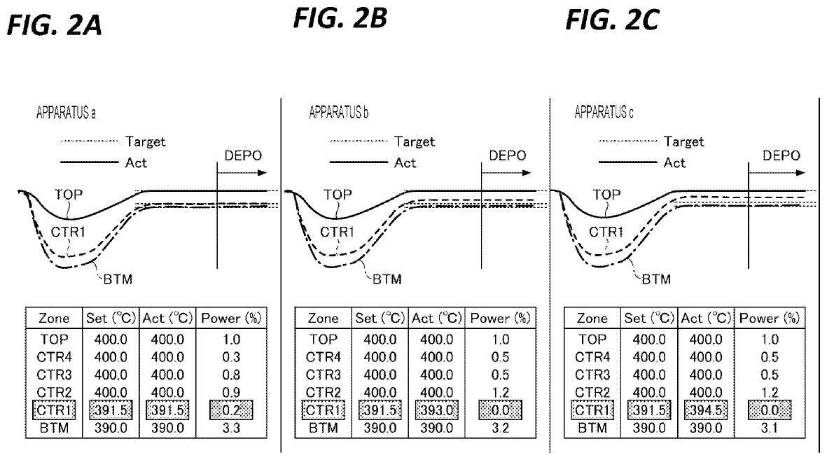

FIGS. 2A to 2C are diagrams illustrating an example of temperature control results by the heater 60 in three different substrate processing apparatuses 1 (apparatus a, apparatus b, and apparatus c). The apparatus a, the apparatus b, and the apparatus c are different substrate processing apparatuses having the same configuration as illustrated in FIG. 1.

In the apparatuses a to c used to obtain the results of FIGS. 2A to 2C, the wafer boat 48 was divided into six zones: “BTM,” “CTR-1,” “CTR-2,” “CTR-3,” “CTR-4,” and “TOP” in order from the bottom. Then, the temperature was controlled by six heaters 60 for each zone. The set temperature of each zone is indicated by Set (° C.). Further, the measured value of the temperature of each zone (measured temperature) measured by the temperature sensor 65 provided in each zone is indicated by Act (° C.). The output value of each heater 60 is indicated in Power (%). Power (%) is a ratio (%) of the output value (power) of the heater 60 when the rated power that may be supplied from each heater 60 to each zone is taken as 100%.

Set (° C.) is set to a temperature at which the film thickness of the substrate W is checked for each zone when the substrate processing apparatus 1 (apparatus a in FIG. 2A) is started up, and the film has an expected thickness. The set temperature calculated using the apparatus a indicated by Set (° C.) in FIG. 2A was also applied to the apparatuses b and c in FIGS. 2B and 2C.

The set temperature for each zone may have a temperature gradient (tilt) in order to obtain constant process performance. For example, the set temperature of each zone indicated by Set (° C.) in FIGS. 2A to 2C is 400° C. from “TOP” to “CTR2,” but is set to 391.5° C. for “CTR1” and 390° C. for “BTM.” For example, heat rises from the bottom to the top in the processing container 4 accommodating the wafer boat 48 illustrated in FIG. 1. Therefore, in the “BTM” and “CTR1” zones, the set temperatures are set slightly lower than in the zones above them.

The output of each heater corresponding to each zone was controlled to achieve the set temperature of each zone. As a result, in the apparatus a, as illustrated in the graph of FIG. 2A, the temperature (Act) of each zone measured by the temperature sensor of each zone was able to be controlled to the set temperature in any of the “TOP,” “CTR1,” and “BTM” zones with respect to the set temperature (target). In the graphs of FIGS. 2A to 2C, the temperature control for zones other than “TOP,” “CTR1,” and “BTM” is omitted. As illustrated in the table of FIG. 2A, the power indicating the output value of the heater is 0.2% in the “CTR1” zone, which is the lowest value, and the power is or more in all zones, which means that the heater 60 is controllable.

Meanwhile, in the apparatuses b and c, as illustrated in the tables of FIGS. 2B and 2C, the power indicating the output value of the heater is 0% in the “CTR1” zone, which means that the heater 60 is uncontrollable. From these results, it was found that the temperature could or could not be adjusted to the set temperature for each zone, depending on individual differences in the substrate processing apparatus 1.

That is, in the two apparatuses b and c used in FIGS. 2B and 2C, the measured temperature (Act) is higher than the set temperature (Set), and the heater output value (Power) is 0%. Thus, the heater is uncontrollable. Due to the presence of such a zone in which the temperature cannot be controlled to the set temperature, a constant process performance cannot be reproduced in the substrate processing.

One of the reasons why the heater output value (Power) became 0% in the “CTR1” zone and the temperature control by the heater 60 became impossible is that when controlling to different set temperatures in adjacent zones, a temperature interference occurs, which makes temperature control difficult.

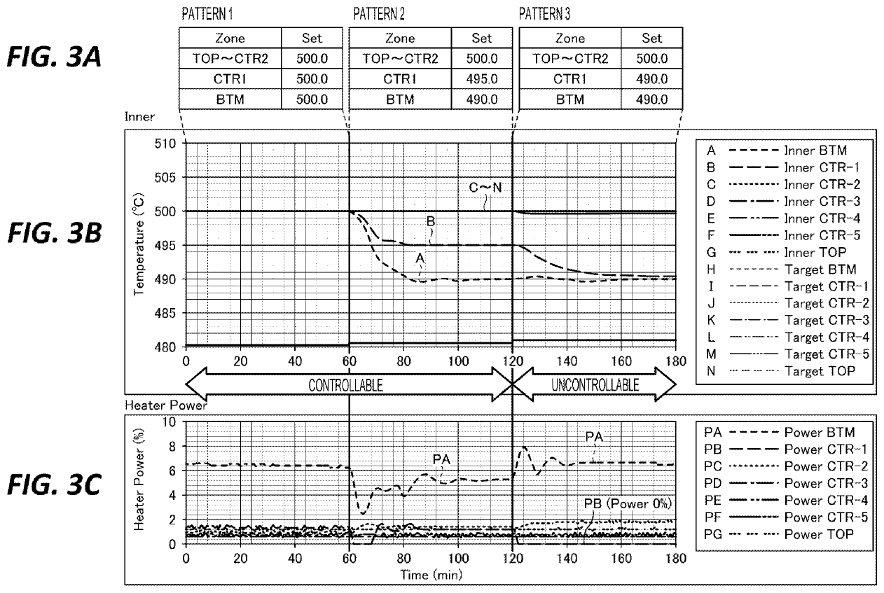

FIGS. 3A to 3C are diagrams illustrating an example of the results of temperature control by the heater 60 with respect to set temperatures for each of three patterns of zones with different temperature gradients (tilts) using the same substrate processing apparatus 1. Here, the substrate processing apparatus 1 as illustrated in FIG. 1 was used. That is, the wafer boat 48 was divided into seven zones: “BTM,” “CTR-1,” “CTR-2,” “CTR-3,” “CTR-4,” “CTR-5,” and “TOP” in order from the bottom. Then, the temperature was controlled by seven heaters 60 for each zone.

FIG. 3A illustrates set temperatures for each zone of three patterns with different temperature gradients (tilts). In Pattern 1, the set temperature (Set) for all seven zones is set to 500° C. In Pattern 2, the set temperature (Set) for each zone of “TOP” and “CTR-5” to “CTR-2” is set to 500° C., the set temperature for each zone of “CTR-1” is set to 495° C., and the set temperature for each zone of “BTM” is set to 490° C. In Pattern 3, the set temperature (Set) for each zone of “TOP” and “CTR-5” to “CTR-2” is set to 500° C., the set temperature for each zone of “CTR-1” and “BTM” is set to 490° C.

The vertical axis of FIG. 3B is a temperature, which indicates the measured temperature of each zone in the inner cylinder 6 of the processing container 4 and the set temperature (target) of each zone. The vertical axis of FIG. 3C indicates a heater output value (Power) of each zone.

The horizontal axes in FIGS. 3B and 3C indicate time. The temperature control of Pattern 1 was performed for 0 minutes to 60 minutes. The temperature control of Pattern 2 was performed for 60 minutes to 120 minutes. The temperature control of Pattern 1 was performed for 120 minutes to 180 minutes.

As a result, in the case of the set temperatures of Patterns 1 and 2, the output value of the heater could be controlled, and the temperature of each zone could be controlled with high accuracy. Meanwhile, in the case of the set temperature of Pattern 3, the output value of the heater 60 for the “CTR-1” zone was 0%, so that the heater becomes uncontrollable (PB: Power CTR-1).

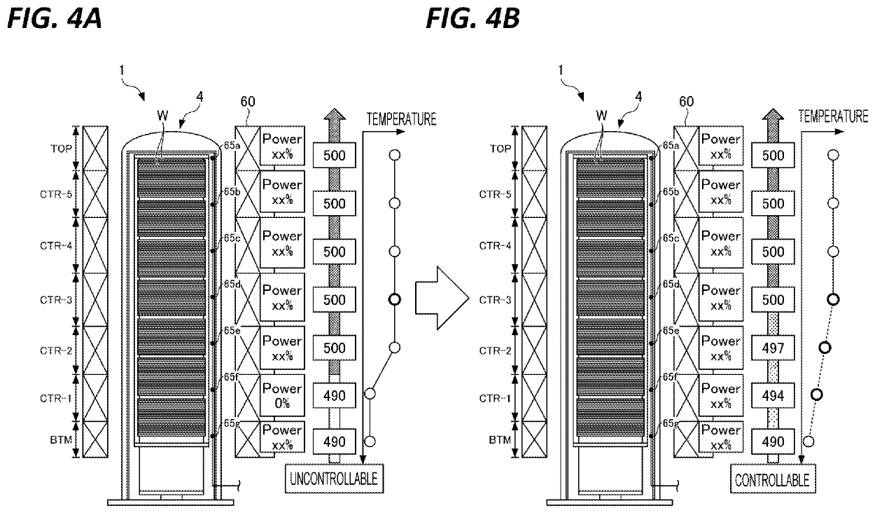

That is, at the set temperature having the temperature gradient of Pattern 3, as illustrated in FIG. 4A, the output value (power) of the heater 60 of “CTR-1” becomes 0%, so that a constant process performance cannot be reproduced in the substrate processing.

Meanwhile, in the case of the set temperature having the temperature gradient of Pattern 2, or in the case of the set temperature having the gentle temperature gradient as illustrated in FIG. 4B, the output value of the heater 60 does not become 0%, so that the heater 60 becomes controllable.

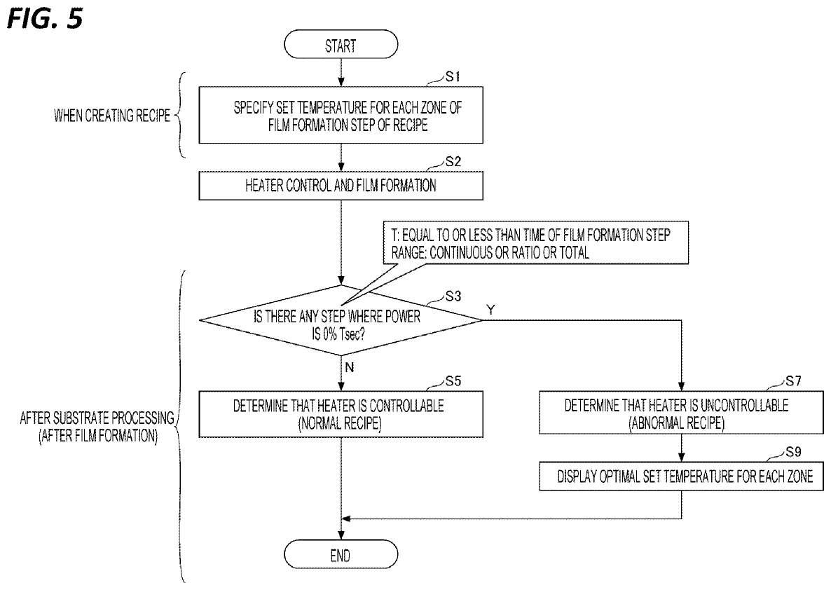

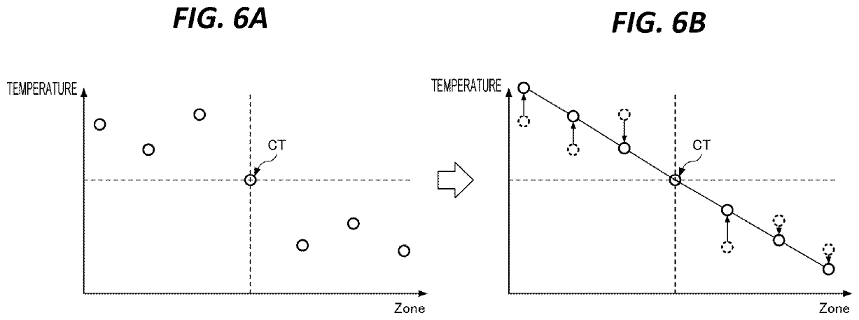

As described above, in the substrate processing method of the present disclosure, it is determined whether the heater 60 is controllable or not, and a warning is issued as necessary. Further, the substrate processing method of the present disclosure automatically calculates and displays a set temperature having an appropriate temperature gradient. Hereinafter, the substrate processing method of the present disclosure will be described with reference to FIGS. 5, 6A, and 6B.

FIG. 5 is a flowchart illustrating an example of the substrate processing method according to an embodiment. FIGS. 6A and 6B are diagrams illustrating an example of the automatic calculation of set temperatures according to one embodiment. The substrate processing method illustrated in FIG. 5 is controlled by, for example, the control device 100 and executed by the substrate processing apparatus 1.

In the present process, step S1 is executed when a recipe is created, and steps S3 to S9 are executed after the substrate processing. The substrate processing is, for example, a film formation processing. Hereinafter, descriptions will be made on an example of causing each part of the substrate processing apparatus 1 to perform the substrate processing in accordance with film formation conditions (film formation steps) set in the recipe.

In step S1, the control device 100 specifies (sets) the set temperature for each zone of the film formation step of the recipe. The control device 100 may set the set temperature for each zone in the recipe for each film formation step according to the user's (operator's) operation. A set temperature for each zone, which is a result of automatically calculating a set temperature having an appropriate temperature gradient to be described later, may be automatically set in the recipe for each film formation step.

When the film formation step starts, as shown in step S2, the plurality of heaters are controlled such that the temperature of each zone becomes the set temperature for each of the plurality of zones set in the recipe, thereby performing the plurality of film formations accommodated.

After the substrate processing (the film formation), in step S3, the control device 100 determines whether there is a step where the output value (Power) of at least one of the plurality of heaters 60 is 0% for Tsec or more. When it is determined in step S3 that there is no step where the heater output value is 0% for Tsec or more, the process proceeds to step S5. Then, the control device 100 determines that the set temperature for each zone set in the recipe is normal, and the heater 60 is controllable, and the process ends.

Meanwhile, when it is determined in step S3 that there is a step where the heater output value is 0% for Tsec or more, the process proceeds to step S7. In step S7, the control device 100 determines that the set temperature for each zone set in the recipe is abnormal, and the heater is uncontrollable. Then, the control device 100 issues an alarm.

Next, in step S9, the control device 100 automatically calculates the optimal set temperature for each zone, displays the calculated optimal set temperature for each zone, and terminates this process. For example, FIG. 4B illustrates a display example of the optimal set temperature for each zone as a result of calculation. In step S9, the control device 100 may automatically specify (set) the calculated set temperature for each of the plurality of zones to the corresponding step of the recipe for executing the substrate processing.

Referring to FIGS. 6A and 6B, descriptions will be made on an example of a method for automatically calculating the optimal set temperature for each zone in step S9. In FIGS. 6A and 6B, the horizontal axises indicate zones, and the vertical axises indicate temperature. Using the center temperature CT (the temperature of “CTR-3” in this example) as a reference for the set temperatures for each of the seven zones illustrated in FIG. 6A, and using the reference central temperature CT as an anchor, the control device 100 linearly interpolates adjacent set temperatures using, for example, the least-squares method. The control device 100 displays the linearly interpolated set temperatures, and indicates that the heater is controllable at the displayed set temperature for each zone. A device that displays the set temperatures may be the control device 100 or another information processing device that can communicate with the control device 100.

[Abnormal Determination Condition]

The determination condition illustrated in step S3 of FIG. 5 is an example of the abnormality determination condition. “T” in the determination condition “Tsec or more when the output value (Power) of the plurality of heaters 60 is 0%” may be the time for each film formation (substrate processing) step, or may be shorter than the time of the film forming step.

Further, “T” in the determination condition may be the continuous time during which the output value of the heater is 0% or the total time within the time of the film formation step, or may be A ratio of the time during which the output value of the heater is 0% to the time of the film formation step.

Further, the abnormality determination condition is not limited to the determination condition that “out of the plurality of heaters 60, the state where the output value (Power) is 0% is Tsec or more.” For example, when the output value of the heater in each zone is 0.2% or less, it may be determined that, as a result of controlling the heater 60 such that each zone reaches the set temperature, the output value of the heater 60 is almost not output (close to 0%), and the heater 60 is uncontrollable. That is, in order to be able to control the heater 60 such that each zone is at the set temperature, the output power of each zone may be defined as “exceeding at least 0.2%.” That is, as an example of the abnormality determination condition, it is not limited to the time when the output value of the heater is 0%, but it is also possible to use a determination condition that “a state where the output value (Power) of any one of the heaters 60 is 0.2% or less is equal to or greater than Tsec.”

However, the numerical value of the output power explained above is an example, and the resolution of control changes as appropriate depending on the configuration of the substrate processing apparatus 1 and the like. For this reason, as an example of the abnormality determination condition, the determination criterion is not limited to whether or not the output value of the heater is 0.2% or less, but it is also possible to use the determination condition that “a state where the output value of any one of the heaters 60 among the plurality of heaters 60 is equal to or less than the control resolution of the heater is equal to or greater than Tsec.” For example, the heater control resolution may be 0.1.

According to the substrate processing method and the substrate processing apparatus 1 described above, it is possible to determine and notify the quality of heater control based on the set temperature for each of a plurality of zones for temperature control of a plurality of substrates.

According to the substrate processing method and the substrate processing apparatus 1 described above, it is possible to determine the quality of heater control based on the set temperature for each of a plurality of zones for temperature control of a plurality of substrates.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container in which a plurality of substrates are processed;
a plurality of heaters configured to control a temperature of the plurality of substrates accommodated in the processing container for each of a plurality of zones; and
a controller configured to control an operation of the plurality of heaters,
wherein the controller is configured to:
control the plurality of heaters to a set temperature set in advance for each of the plurality of zones, thereby performing a processing on the plurality of substrates accommodated in the processing container,
determine whether an abnormality determination condition is satisfied, including that an output value of at least one heater of the plurality of heaters is equal to or less than a heater control resolution, and
issue a warning for the set temperature for each of the plurality of zones based on a result of the determining.

2. The substrate processing apparatus according to claim 1, wherein the controller is further configured to:
calculate an appropriate value of the set temperature for each of the plurality of zones based on a center temperature among the set temperatures of the plurality of zones, and
display the calculated set temperature for each of the plurality of zones.

3. The substrate processing apparatus according to claim 1, wherein the controller determines whether the abnormality determination condition is satisfied based on a ratio of a time during which the output value of the at least one heater is equal to or less than the heater control resolution to a processing time of the plurality of substrates.

4. The substrate processing apparatus according to claim 1, wherein the controller determines whether the abnormality determination condition is satisfied based on a total time or continuous time during which the output value of the at least one heater is equal to or less than the heater control resolution, during a processing time of the plurality of substrates.

5. The substrate processing apparatus according to claim 1, wherein the heater control resolution is 0.1.

6. The substrate processing apparatus according to claim 1, further comprising:
a boat configured to accommodate the plurality of substrates within the processing container in a vertical direction,
wherein the set temperature for each of the plurality of zones is set for each of the plurality of zones in the vertical direction of the boat, and
the controller adjusts the temperature of the plurality of heaters to the set temperature for each of the plurality of zones in the vertical direction of the boat.

7. The substrate processing apparatus according to claim 1, wherein the controller determines whether the abnormality determination condition is satisfied after the processing on the plurality of substrates.

8. The substrate processing apparatus according to claim 2, wherein the controller automatically sets the calculated set temperature for each of the plurality of zones to a recipe for processing the plurality of substrates.

9. A substrate processing method comprising:
providing a substrate processing apparatus including:
a processing container in which a plurality of substrates are processed; and
a plurality of heaters configured to control a temperature of the plurality of substrates accommodated in the processing container for each of a plurality of zones;
controlling the plurality of heaters to a set temperature set in advance for each of the plurality of zones, thereby performing a processing on the plurality of substrates accommodated in the processing container,
determining whether an abnormality determination condition is satisfied, including that an output value of at least one heater of the plurality of heaters is equal to or less than a heater control resolution, and
issuing a warning for the set temperature for each of the plurality of zones based on a result of the determining.
